(19) United States
(12) Patent Application Publication
(10) Pub. No.: US 2003/0119218 A1
(43) Pub. Date: Jun. 26, 2003

(54) Light emitting device and manufacturing method thereof

(75) Inventor: Jun Ho Jang, Seoul (KR)

Correspondence Address: FLESHNER & KIM, LLP, P.O. Box 221200, Chantilly, VA, 20153-1200, US

(73) Assignee: LG Electronics Inc.

(21) Appl. No.: 10/318,191

(22) Filed: Dec. 13, 2002

(30) Foreign Application Priority Data
Dec. 20, 2001 (KR) P 2001-81876

(51) Int. Cl. H01L 21/00

(52) U.S. Cl. 438/46; 438/42; 438/47; 257/466

(57) ABSTRACT

Disclosed is a light emitting device capable of increasing the light power and manufacturing method thereof. The light emitting device includes: a first compound semiconductor layer formed on a substrate and having an etched predetermined region at an upper portion thereof; a second compound semiconductor layer formed on a non-etched region of the first compound semiconductor layer and having a rugged region including a plurality of grooves; a transparent electrode formed on the second compound semiconductor layer; a first electrode formed on the transparent electrode; and a second electrode formed on the etched region of the first compound semiconductor layer.

This application claims the benefit of the Korean Application No. P 2001-81876 filed on Dec. 20, 2002, which is hereby incorporated by reference.

### BACKGROUND OF THE INVENTION

1. Field of the Invention

The present invention relates to a light emitting device, and more particularly, to a light emitting device capable of increasing the light power and lowering the driving voltage thereof, and a manufacturing method thereof.

2. Discussion of the Related Art

Generally, group III-V compound semiconductors have a high luminous efficiency and can reproduce red to purple light by adjusting indium concentration. Among group III-V compound semiconductors, nitride semiconductor (InₓAl_{y}Ga_{1-x-y}N, 0≦X, 0≦Y. X+Y≦1) is particularly used for the fabrication of the light emitting diode and the laser diode.

Light emitting diode is a diode which emits an excess energy in the form of light when electron and hole are recombined, and includes green light emitting diode using GaP, blue light emitting diode using InGaN/AlGaN double hetero structure, etc. These light emitting diodes are widely being used in various technical fields such as digit and character display device, signal lamp sensor, optical coupling device and the like because of low voltage and low power advantages.

FIG. 1 is a partial sectional view of a general light emitting diode packaged. Referring to FIG. 1, a light emitting diode is attached to a first leadframe 40 with a high reflectivity by a solder 30. Electrode pads 22 and 23 of the light emitting diode are bonded to the first leadframe 40 and a second leadframe 41 by wires 35. In order to protect the light emitting diode and the bonding portions from an external environment, the light emitting diode and the bonding portions are sealed by a transparent epoxy 50. Only first and second leads 10 and 11 connected with the first and second leadframes 40 and 41 are exposed to an external environment.

In the light emitting diode having the aforementioned structure, an n-type GaN-based group III-V compound semiconductor and a p-type GaN-based group III-V compound semiconductor doped with p-type impurities, are formed on a substrate by a thin film growth method of a metal organic chemical vapor deposition. Between the n-type GaN-based group III-V compound semiconductor and the p-type GaN-based group III-V compound semiconductor, there is arranged an active layer of InₓGa₁₋ₓN (0≦X≦1) which is lower in energy bandgap than the n-type GaN-based group III-V compound semiconductor and the p-type GaN-based group III-V compound semiconductor.

FIG. 2 is a schematic view illustrating a light emitting status in a conventional light emitting diode. As shown in FIG. 2, an n-type GaN layer 27, an active layer 26, and a p-type GaN layer 25 are stacked on a sapphire substrate 28. On the p-type GaN layer 25 is formed a transparent electrode 21. Also, a p-type electrode pad 22 is formed on the transparent electrode 21 and an n-type electrode pad 23 is formed on the n-type GaN layer 27.

If a current is supplied to the active layer 26 through the p-type and n-type electrode pads 22 and 23, light is generated from the active layer 26 and is then emitted to an outside through the transparent electrode 21.

However, in the conventional light emitting diode, the light generated from the active layer 26 is not completely emitted but is blocked by or is absorbed in the p-type electrode pad 22 on the transparent electrode 21, so that there occurs a problem in that the light power efficiency is lowered.

### SUMMARY OF THE INVENTION

Accordingly, the present invention is directed to a light emitting device and manufacturing method thereof that substantially obviates one or more problems due to limitations and disadvantages of the related art.

An object of the present invention is to provide a light emitting device capable of increasing the light power and lowering the driving voltage and a manufacturing method thereof.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a light emitting device includes: a first compound semiconductor layer formed on a substrate and having an etched predetermined region at an upper portion thereof; a second compound semiconductor layer formed on a non-etched region of the first compound semiconductor layer and having a rugged region including a plurality of grooves; a transparent electrode formed on the second compound semiconductor layer; a first electrode formed on the transparent electrode; and a second electrode formed on the etched region of the first compound semiconductor layer.

The rugged region is formed at an upper surface of the second compound semiconductor layer corresponding to a location of the first electrode, have an area that is the same as an area of the first electrode. Also, the plurality of grooves of the rugged region are formed to have a constant size and interval.

In another aspect of the present invention, a light emitting device includes: an n-type compound semiconductor layer formed on a substrate and having an etched predetermined region at an upper portion thereof, said etched predetermined region including a first rugged region including a plurality of grooves; an active layer formed on a non-etched region of the n-type compound semiconductor layer; a p-type compound semiconductor layer formed on the active layer and having a second rugged region including a plurality of successive grooves; a transparent electrode formed on the p-type compound semiconductor layer; a p-type electrode formed on the transparent electrode; and an n-type electrode formed on the first rugged region of the n-type compound semiconductor layer.

In another aspect of the present invention, there is provided a method for manufacturing a light emitting device. The method includes the steps of: (a) sequentially forming an n-type compound semiconductor layer and a p-type compound semiconductor layer on a substrate; (b) selectively etching the n-type compound semiconductor layer and the p-type compound semiconductor layer such that a predetermined region on the n-type compound semiconductor layer is exposed; (c) forming a rugged region including a plurality of grooves at a predetermined region of an upper surface of the p-type compound semiconductor layer; (d) forming a transparent electrode on the p-type compound semiconductor layer; and (e) forming a p-type electrode on the transparent electrode corresponding to a location where the rugged region is placed, and an n-type electrode on an exposed predetermined region of the n-type compound semiconductor layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a partial sectional view of a general light emitting diode packaged;

FIG. 2 is a sectional view of a conventional light emitting diode;

FIG. 3 is a sectional view of a light emitting diode according to a first embodiment of the present invention;

FIGS. 4A to 4F are sectional views for illustrating a manufacturing process of the light emitting device of FIG. 3;

FIG. 5 is a sectional view of a light emitting diode according to a second embodiment of the present invention; and

FIGS. 6A to 6F are sectional views for illustrating a manufacturing process of the light emitting device of FIG. 5.

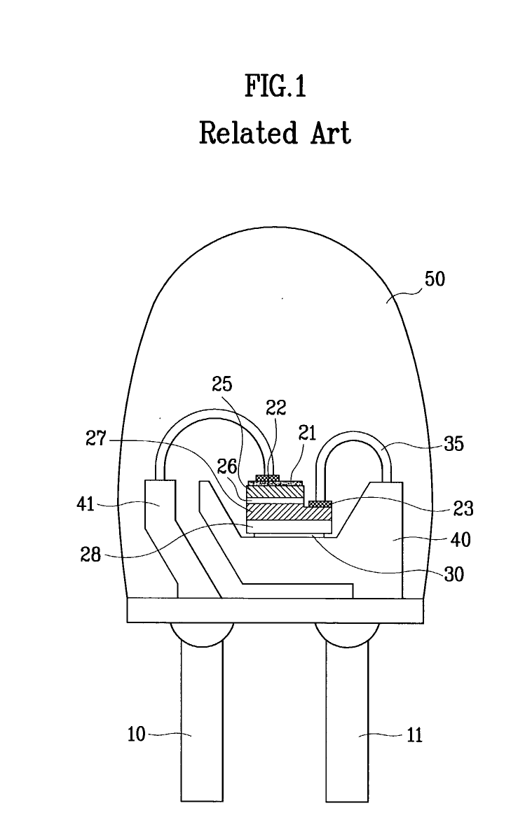

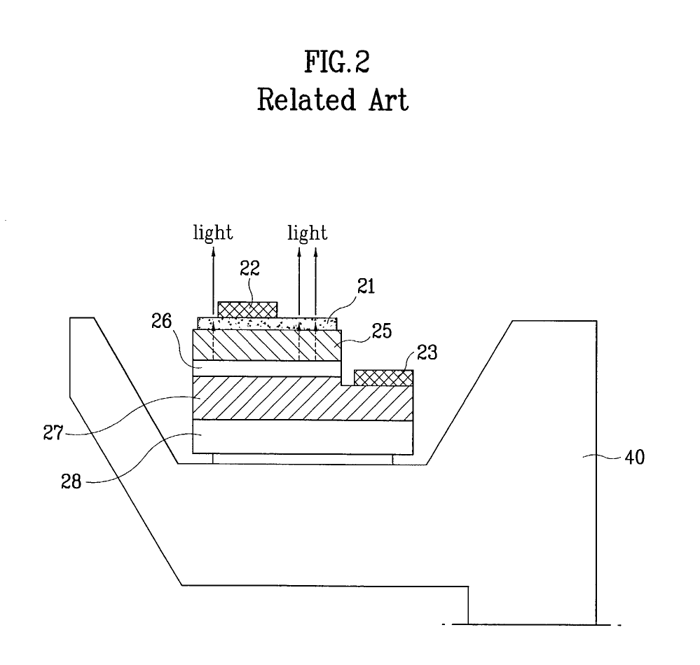

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

First Embodiment

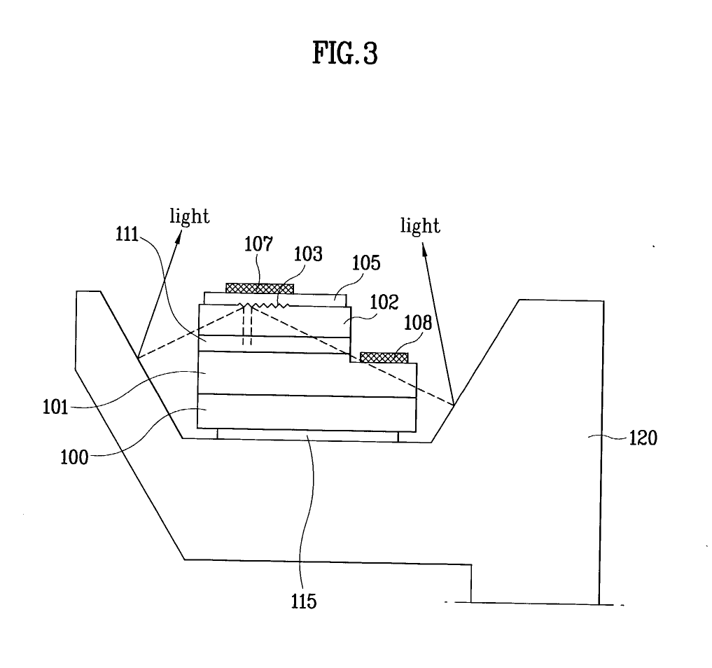

FIG. 3 is a sectional view of a light emitting diode according to a first embodiment of the present invention.

As shown in FIG. 3, an n-type compound semiconductor layer 101 having a selected region exposed by an etch is arranged on a sapphire substrate 100. An n-type electrode 108 is arranged on a selected portion of the exposed region of the n-type compound semiconductor layer 101. On the remaining region of the n-type compound semiconductor layer 101 are stacked an active layer 111 and a p-type compound semiconductor layer 102. The p-type compound semiconductor layer 102 has a rugged region 103 including a plurality of successive grooves. A transparent electrode 105 is arranged on the p-type compound semiconductor layer 102, and a p-type electrode 107 is arranged on the transparent electrode 105. The light emitting diode having the above structure is attached to a leadframe 120 by a solder 115.

The rugged region 103 reflects light emitted toward the p-type electrode 107 from the active layer 111, and the light reflected by the rugged region 103 is again reflected by the leadframe 120 that is a dishlike aluminum plate. Accordingly, the light emitted toward the p-type electrode 107 can be emitted to the outside.

Next, a manufacturing process of the light emitting device of the first embodiment having the above structure is described.

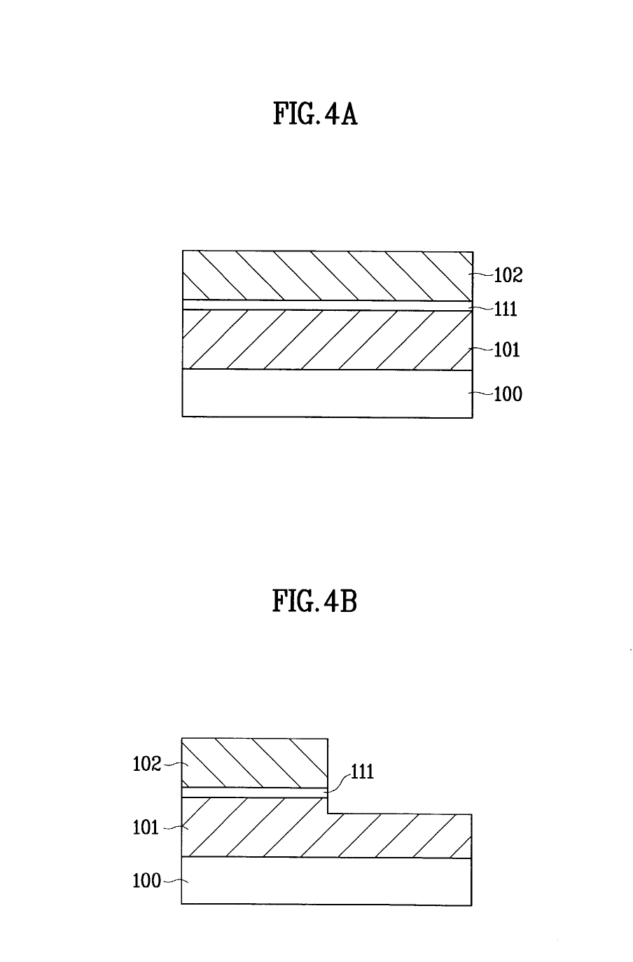

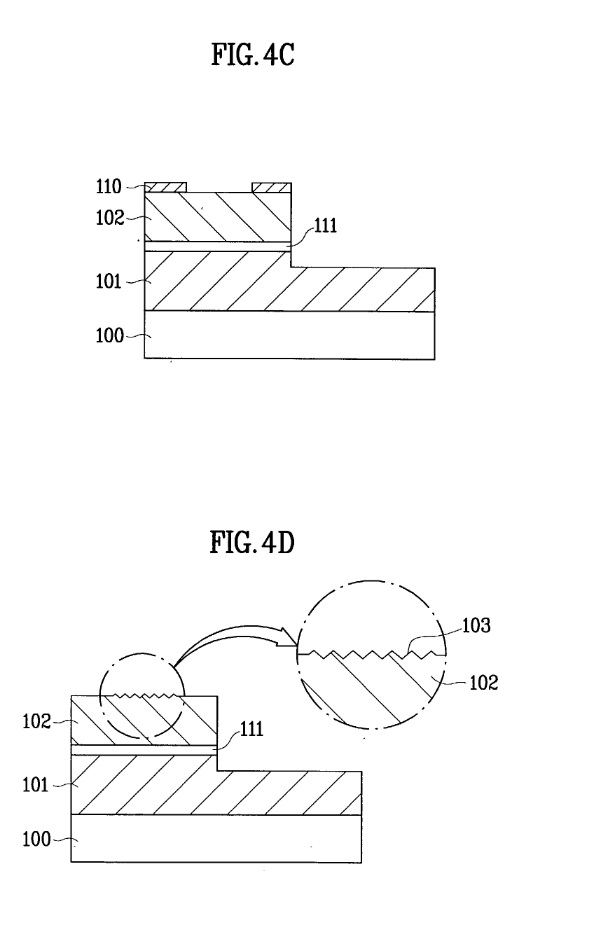

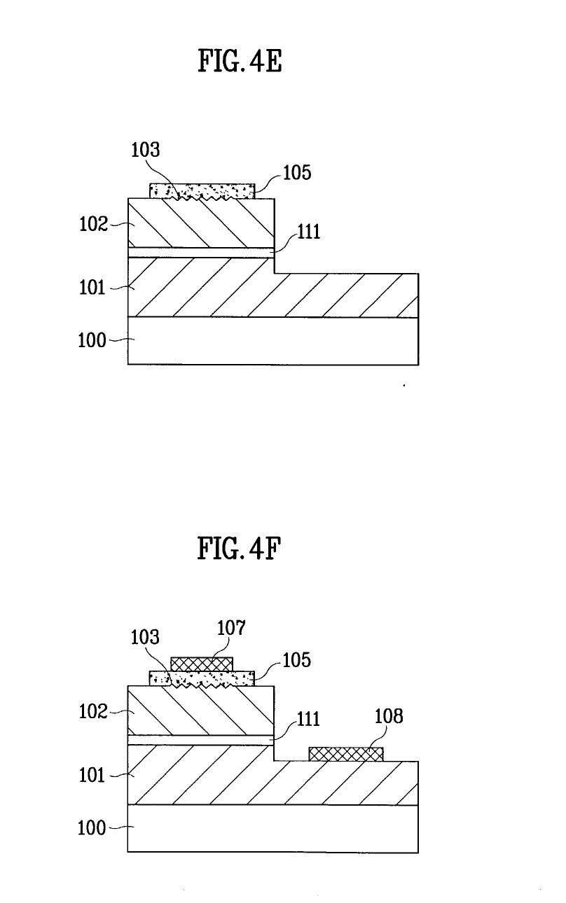

FIGS. 4A to 4F are sectional views for illustrating a manufacturing process of the light emitting device of FIG. 3.

As shown in FIG. 4A, a buffer layer (not shown) is formed on a substrate 100, and then an n-type compound semiconductor layer 101 doped with n-type impurities is formed by a metal organic chemical vapor deposition (MOCVD) method. The substrate 100 is preferably a sapphire substrate.

After that, an active layer 111 and a p-type compound semiconductor layer 102 doped with p-type impurities are sequentially formed on the n-type compound semiconductor layer 101 and then a heat treatment is carried out.

Here, the n-type compound semiconductor layer 101 and the p-type compound semiconductor layer 102 are formed of one selected from a group consisting of GaAs, GaP, GaAs₁₋ₓPₓ, Ga₁₋ₓAlₓAs, InP and In₁₋ₓGaₓP. Also, the active layer 111 is formed of a material having an energy gap smaller than the n-type compound semiconductor layer 101 and the p-type compound semiconductor layer 102. However, since an interface formed by a junction of the n-type compound semiconductor layer 101 and the p-type compound semiconductor layer 102 can perform the role of the active layer 111 without the active layer 111, the forming step of the active layer 111 can be omitted.

Afterwards, as shown in FIG. 4B, a selected region of the p-type compound semiconductor layer 102 and the active layer 111 and a part of the upper portion of the n-type compound semiconductor layer 101 are removed, so that the n-type compound semiconductor layer 101 is partially exposed.

Thereafter, as shown in FIG. 4C, a mask 110 is formed on the p-type compound semiconductor layer 102. Since the mask 110 is formed at an edge of the upper surface of the p-type compound semiconductor layer 102, a selected portion of the upper surface of the p-type compound semiconductor layer 102 is exposed. The area and location of the upper surface of the p-type compound semiconductor layer 102 correspond to the area and location of a p-type electrode 107 to be formed.

After that, as shown in FIG. 4D, the resultant substrate is subject to a reactive ion etching (RIE) process using the mask 110, so that a rugged region 103 having a plurality of successive grooves is formed on the exposed upper surface of the p-type compound semiconductor layer 102. For the grooves to serve as a diffraction grating, they are preferably formed to have a constant size and interval. In addition, the slopes of the grooves should have a constant critical angle. The rugged region formed in the p-type compound semiconductor layer 102 is to prevent light emitted from the active layer 111 from being blocked by or absorbed in the p-type electrode 107.

Afterwards, as shown in FIG. 4E, a transparent electrode 105 for current diffusion is formed on the p-type compound semiconductor layer 102. The transparent electrode 105 is formed to have an area in which the rugged region 103 is completely covered.

Thereafter, as shown in FIG. 4F, a p-type electrode 107 is formed on the transparent electrode 105 and at the same time an n-type electrode 108 is formed on the exposed region of the n-type compound semiconductor layer 101. The p-type electrode 107 is formed at a location corresponding to the rugged region 103. Then, the resultant substrate 100 is attached to a leadframe 120 using a solder 115.

Second Embodiment

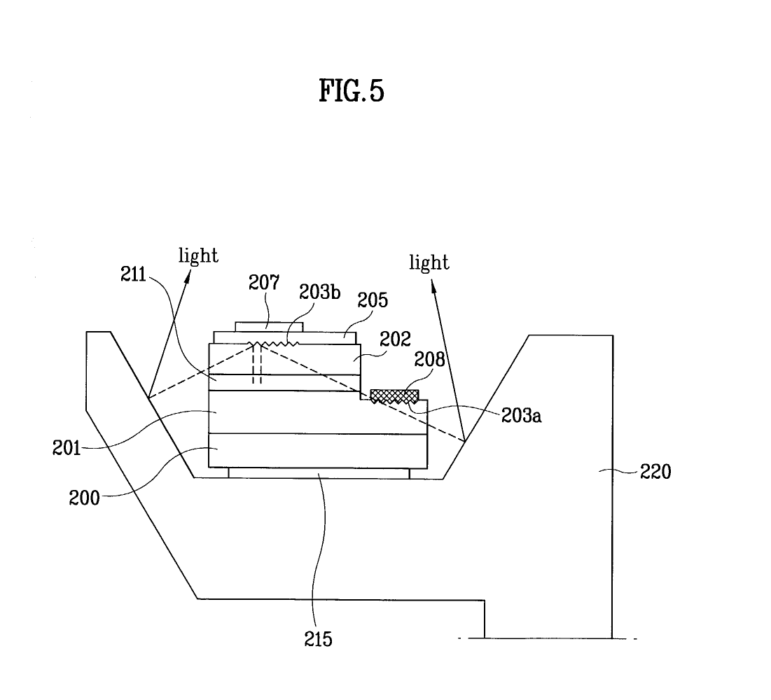

FIG. 5 is a sectional view of a light emitting diode according to a second embodiment of the present invention.

A light emitting device according to a second embodiment of the present invention is similar to that of the first embodiment, but has differences in that a rugged region including successive grooves is formed on the upper surface of an n-type compound semiconductor layer beneath an n-type electrode as well as on the upper surface of a p-type compound semiconductor layer beneath a p-type electrode.

As shown in FIG. 5, an n-type compound semiconductor layer 101 having a selected region exposed by an etch is arranged on a sapphire substrate 200. An n-type electrode 208 is arranged on a selected portion of the exposed region of the n-type compound semiconductor layer 201. On the remaining region of the n-type compound semiconductor layer 201 are stacked an active layer 211 and a p-type compound semiconductor layer 202. The n-type compound semiconductor layer 201 has a first rugged region 203a including a plurality of successive grooves beneath the n-type electrode 208 and the p-type compound semiconductor layer 202 has a second rugged region 203b including a plurality of successive grooves at a selected region of the upper surface thereof.

A transparent electrode 205 is arranged on the p-type compound semiconductor layer 202, and a p-type electrode 207 is arranged on the transparent electrode 205. The substrate 200 is attached to a leadframe 220 by a solder 215.

The first rugged region 203a is provided to lower contact resistance between the n-type compound semiconductor layer 201 and the n-type electrode 208, and the second rugged region 203b is provided to prevent the light emitted from the active layer 211 from being blocked by or being absorbed in the p-type electrode 207. As a result, the light emitting device according to the second embodiment can increase the light power and decrease the driving voltage due to the decrease in the contact resistance.

Next, a manufacturing process of the light emitting device of the second embodiment having the above structure is described.

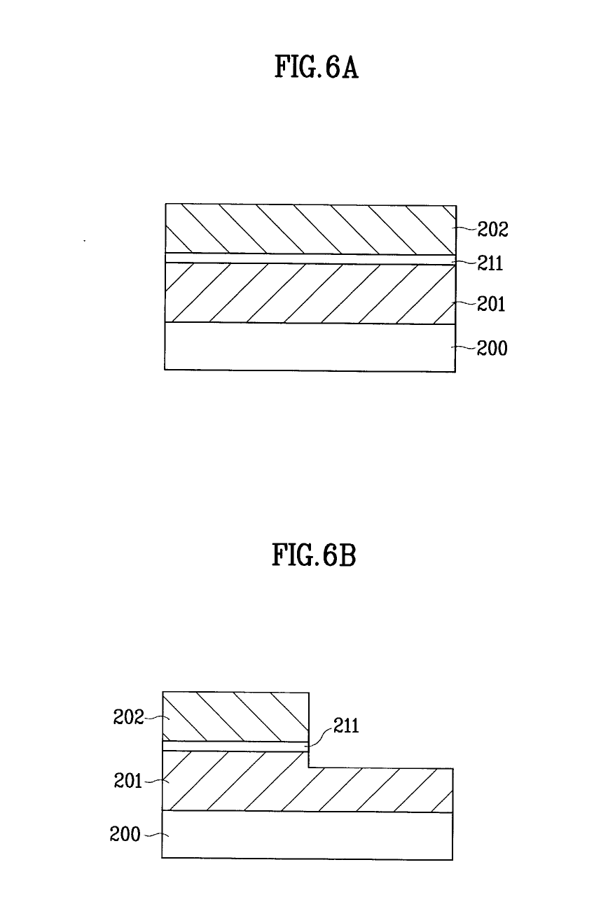

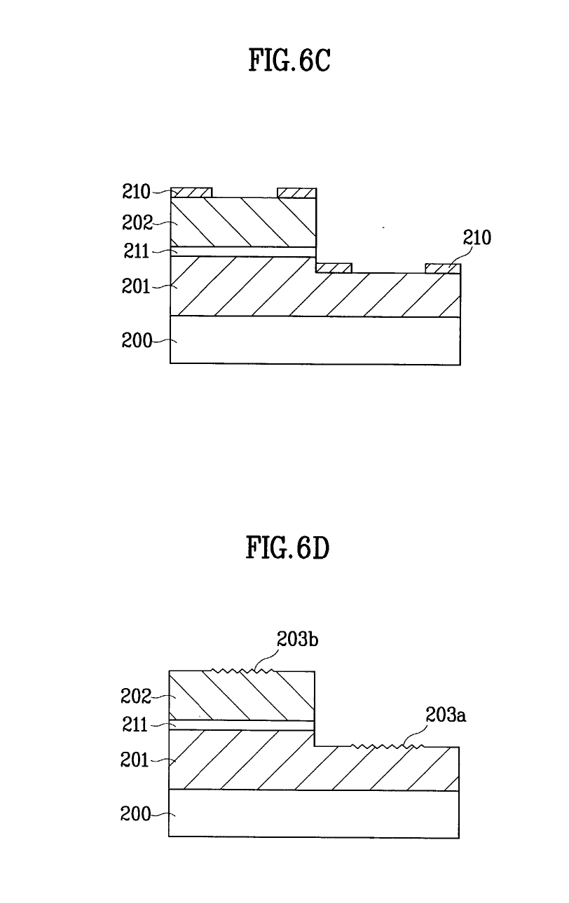

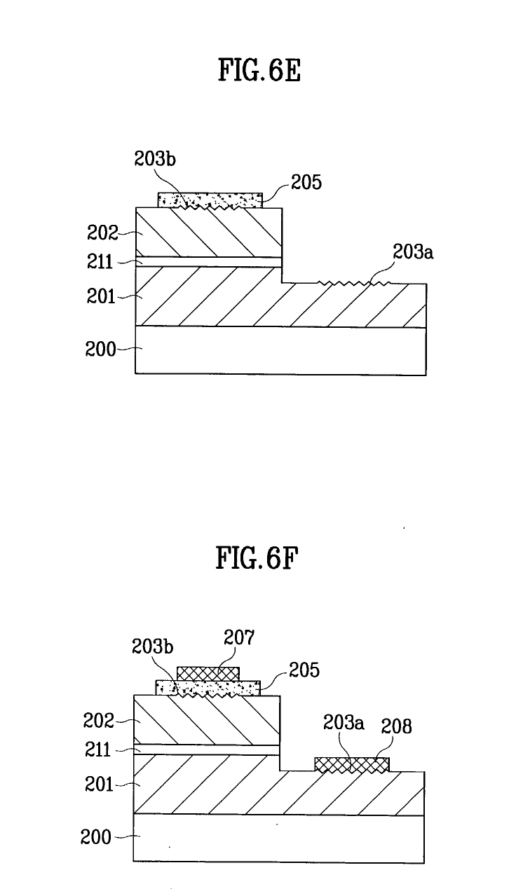

FIGS. 6A to 6F are sectional views for illustrating a manufacturing process of the light emitting device of FIG. 5.

As shown in FIG. 6A, an n-type compound semiconductor layer 201 doped with n-type impurities is formed on a substrate 200 by a metal organic chemical vapor deposition (MOCVD) method. After that, an active layer 211 and a p-type compound semiconductor layer 202 are sequentially formed on the n-type compound semiconductor layer 201 and then a heat treatment is carried out. Here, the n-type compound semiconductor layer 201 and the p-type compound semiconductor layer 202 are formed of one selected from a group consisting of GaAs, GaP, GaAs₁₋ₓPₓ, Ga₁₋ₓAlₓAs, InP and In₁₋ₓGaₓP. Also, like the first embodiment, since an interface between the n-type compound semiconductor layer 201 and the p-type compound semiconductor layer 202 can perform the role of the active layer 211 without the active layer 211, the forming step of the active layer 211 can be omitted.

Afterwards, as shown in FIG. 6B, a selected region of the p type compound semiconductor layer 202 and the active layer 211 and a part of the upper portion of the n-type compound semiconductor layer 201 are removed, so that the n-type compound semiconductor layer 201 is partially exposed.

Thereafter, as shown in FIG. 6C, a mask 210 is formed on the upper surface of the n-type compound semiconductor layer 201 and the upper surface of the p-type compound semiconductor layer 202.

After that, as shown in FIG. 6D, the resultant substrate is subject to a reactive ion etching (RIE) process using the mask 210, so that first and second rugged regions 203a and 203b each having a plurality of successive grooves are respectively formed on the exposed upper surfaces of the n-type compound semiconductor layer 201 and the p-type compound semiconductor layer 202. Here, the area of the first rugged region 203a corresponds to the area of the n-type electrode 208 and the area of the second rugged region 203b corresponds to the area of the p-type electrode 207. In addition, for the grooves of the second rugged region 203b to serve as a diffraction grating, they are preferably formed to have a constant size and interval. Moreover, the slopes of the grooves should have a constant critical angle.

Afterwards, as shown in FIG. 6E, a transparent electrode 205 for current diffusion is formed on the p-type compound semiconductor layer 202. The transparent electrode 205 is formed to have an area in which the second rugged region 203b is completely covered.

Thereafter, as shown in FIG. 6F, a p-type electrode 207 is formed on the transparent electrode 205 and at the same time an n-type electrode 208 is formed on the exposed region of the n-type compound semiconductor layer 201. Here, the p-type electrode 207 is formed at a location corresponding to the second rugged region 203b and the n-type electrode 208 is formed at a location corresponding to the first rugged region 203a.

Then, the resultant substrate 200 is attached to a leadframe 220 using a solder 215.

As described previously, according to the present invention, a rugged region including grooves capable of reflecting light is formed beneath the p-type electrode to increase the light power, and another rugged region capable of lowering the contact resistance is formed beneath the n-type electrode to lower the driving voltage of the device.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A light emitting device comprising:
a first compound semiconductor layer formed on a substrate and having an etched predetermined region at an upper portion thereof;
a second compound semiconductor layer formed on a non-etched region of the first compound semiconductor layer and having a rugged region including a plurality of grooves;
a transparent electrode formed on the second compound semiconductor layer; and
a first electrode formed on the transparent electrode; and
a second electrode formed on the etched region of the first compound semiconductor layer.

2. The light emitting device of claim 1, wherein the first and second compound semiconductor layers are made of one selected from a group consisting of GaAs, GaP, GaAs₁₋ₓPₓ, Ga₁₋ₓAlₓ, As, InP and In₁₋ₓGaₓP.

3. The light emitting device of claim 1, wherein the rugged region has an area that is the same as an area of the first electrode.

4. The light emitting device of claim 1, wherein the rugged region is formed on an upper surface of the second compound semiconductor layer corresponding to a location of the first electrode.

5. The light emitting device of claim 4, wherein the grooves are formed to have a constant size and interval.

6. The light emitting device of claim 1, further comprising an active layer placed between the first compound semiconductor layer and the second compound semiconductor layer.

7. The light emitting device of claim 1, wherein the first compound semiconductor layer further comprises a rugged region formed at a surface thereof beneath the second electrode.

8. The light emitting device of claim 6, wherein the rugged region has an area that is the same as an area of the second electrode.

9. A method for manufacturing a light emitting device, the method comprising the steps of:
(a) sequentially forming an n-type compound semiconductor layer and a p-type compound semiconductor layer on a substrate;
(b) selectively etching the n-type compound semiconductor layer and the p-type compound semiconductor layer such that a predetermined region on the n-type compound semiconductor layer is exposed;
(c) forming a rugged region including a plurality of grooves at a predetermined region of an upper surface of the p-type compound semiconductor layer;
(d) forming a transparent electrode on the p-type compound semiconductor layer; and
(e) forming a p-type electrode on the transparent electrode corresponding to a location where the rugged region is placed, and an n-type electrode on an exposed predetermined region of the n-type compound semiconductor layer.

10. The method of claim 9, wherein the rugged region is formed by a reacting ion etching (RIE) process.

11. The method of claim 9, wherein the rugged region is formed to have an area that is the same as an area of the p-type electrode.

12. The method of claim 9, wherein the plurality of grooves are formed to have a constant size and interval.

13. The method of claim 9, wherein the rugged region is formed at the predetermined region of the upper surface of the p-type compound semiconductor layer and the exposed predetermined portion of the n-type compound semiconductor layer.

14. A light emitting device comprising:
an n-type compound semiconductor layer formed on a substrate and having an etched predetermined region at an upper portion thereof, said etched predetermined region including a first rugged region including a plurality of grooves;
an active layer formed on a non-etched region of the n-type compound semiconductor layer;
a p-type compound semiconductor layer formed on the active layer and having a second rugged region including a plurality of successive grooves;
a transparent electrode formed on the p-type compound semiconductor layer;
a p-type electrode formed on the transparent electrode; and
an n-type electrode formed on the first rugged region of the n-type compound semiconductor layer.
